(19) United States
(12) Patent Application Publication
(10) Pub. No.: US 2016/0365536 A1
(43) Pub. Date: Dec. 15, 2016

(54) FLEXIBLE DISPLAY DEVICE PACKAGES AND METHODS OF MANUFACTURING

(71) Applicant: CORNING INCORPORATED, Corning, NY (US)

(72) Inventors: Robert Alan Bellman, Painted Post, NY (US); Dana Craig Bookbinder, Corning, NY (US); Theresa Chang, Painted Post, NY (US)

(21) Appl. No.: 15/120,908

(22) PCT Filed: Feb. 23, 2015
(86) PCT No.: PCT/US15/17031

§ 371 Date: Aug. 23, 2016

Related U.S. Application Data
(60) Provisional application No. 62/003,884, filed on May 28, 2014.
(60) Provisional application No. 61/945,938, filed on Feb. 28, 2014.

(51) Int. Cl. H01L 51/52; H01L 51/56

(52) U.S. Cl. CPC H01L 51/5246; H01L 51/5253; H01L 51/56; H01L 2251/558; H01L 2251/5338

(57) ABSTRACT

A flexible display device package may comprise a barrier (190) on a polymer substrate (120), a display device (110) on the barrier, and a flexible glass sheet (130) bonded to the barrier (190) with a hermetic seal to hermetically encapsulate the display device (110) between the flexible glass sheet (130) and the barrier (190). The flexible glass sheet may comprise a thickness of less than about 0.3 mm.

### CROSS-REFERENCE TO RELATED APPLICATIONS

This application claims the benefit of priority under 35 U.S.C. §119 of U.S. Provisional Application Ser. No. 61/945938 filed on Feb. 28, 2014 and Provisional Application Ser. No. 62/003884 filed on May 28, 2014, the content of which is relied upon and incorporated herein by reference in its entirety.

### FIELD

The following description relates to flexible display device packages and methods of manufacturing and, more particularly, to flexible display device packages and methods of manufacturing flexible display device packages including a flexible glass sheet bonded to a barrier.

### BACKGROUND

Display devices commonly include organic light-emitting diodes (OLEDs). While beneficial in various display applications, OLEDs are known to be sensitive to environmental contaminants such as water.

### SUMMARY

The following presents a simplified summary of the disclosure in order to provide a basic understanding of some example aspects described in the detailed description.

In a first aspect, a flexible display device package includes a barrier on a polymer substrate, a display device on the barrier, and a flexible glass sheet bonded to the barrier with a hermetic seal to hermetically encapsulate the display device between the flexible glass sheet and the barrier. The flexible glass sheet includes a thickness of less than about 0.3 mm.

In one example of the first aspect, the flexible display device further includes a bottom film sheet bonded to a second side of the polymer substrate to hermetically encapsulate the polymer substrate. In one example, the bottom film sheet includes one of metal foil, glass film, polymer film, and any combination thereof.

In another example of the first aspect, the flexible glass sheet is bonded to the barrier by one of lead free solder, gold eutectics, a metal silicide, and a glass seal. In another example, the flexible glass sheet is further bonded to the barrier by an organic seal circumscribing the hermetic seal. For instance, the organic seal can include one of a UV-curable sealing material and a thermoplastic material.

In still another example of the first aspect, the polymer substrate includes a polyimide. In another example, the barrier includes one of a metal film, a glass film, and a combination thereof.

The first aspect may be provided alone or in combination with any one or more of the examples of the first aspect discussed above.

In a second aspect, a method of manufacturing a flexible display device package may include depositing a barrier on a polymer substrate, depositing a display device on the barrier, and bonding a flexible glass sheet to the barrier to hermetically encapsulate the display device between the flexible glass sheet and the barrier. The flexible glass sheet includes a thickness of less than about 0.3 mm

In one example of the second aspect, the method further includes bonding a bottom film sheet to a second side of the polymer substrate to hermetically encapsulate the polymer substrate. In one example, the bottom film sheet includes one of a metal foil, a glass film, a polymer film, and any combination thereof.

In another example of the second aspect, the bonding of the flexible glass sheet includes sealing the barrier to the flexible glass sheet with one of lead free solder, gold eutectics, a metal silicide, and a glass seal. In one example, the method further includes, when the barrier is sealed to the flexible glass sheet with one of lead free solder and gold eutectics, depositing the polymer substrate on a carrier substrate prior to the depositing of the barrier, and aligning the barrier with the flexible glass sheet after the depositing of the barrier and prior to the bonding of the flexible glass sheet.

In still another example of the second aspect, when the barrier is sealed to the flexible glass sheet by the metal silicide, the sealing includes reacting one or more of aluminum, molybdenum, cobalt, and nickel deposited on one of the flexible glass sheet and the barrier with a silicon layer deposited on another of the flexible glass sheet and the barrier.

In yet another example of the second aspect, when the barrier is sealed to the flexible glass sheet by the glass seal, the sealing includes depositing a glass frit on the flexible glass sheet, depositing an oxide or metal contact area on the barrier, and contacting the glass frit and the contact area while heating to form the glass seal.

In still another example of the second aspect, the bonding of the flexible glass sheet includes hermetically sealing the flexible glass sheet to the barrier with a hermetic sealing material, and organically sealing the flexible glass sheet to the barrier with an organic sealing material. The organic sealing material circumscribes the hermetic sealing material. In one example, the organic sealing material comprises a UV-curable sealing material. Organically sealing includes wicking of the UV-curable sealing material between the flexible glass sheet and the barrier and a curing of the UV-curable sealing material. In another example, organically sealing comprises depositing a film of thermoplastic material on the flexible glass sheet to seal the flexible glass sheet to the barrier.

The second aspect may be provided alone or in combination with any one or more of the examples of the second aspect discussed above.

### BRIEF DESCRIPTION OF THE DRAWINGS

These and other features, aspects and advantages of the present disclosure are better understood when the following detailed description is read with reference to the accompanying drawings, in which:

FIG. 1 is a schematic top view illustrating an example of a flexible display device package on a carrier substrate according to an example embodiment of the disclosure;

FIG. 2 is a sectional view of the flexible display device package, prior to sealing, taken along 2-2 in FIG. 1;

FIG. 3 is a sectional view of the flexible display device package, after sealing, taken along 3-3 in FIG. 1;

FIG. 4 is a schematic side view of the flexible display device package of FIG. 1, prior to sealing;

FIG. 5 is a schematic side view of the flexible display device package of FIG. 1, after sealing;

FIG. 6 is a schematic top view illustrating another example incorporating a plurality of flexible display device packages;

FIG. 7 is a schematic top view illustrating another example of a flexible display device package;

FIG. 8 is a schematic side view illustrating still another example of a flexible display device package; and

FIG. 9 is a schematic flow diagram illustrating example steps in methods of manufacturing example flexible display device packages.

### DETAILED DESCRIPTION

Example embodiments will now be described more fully hereinafter with reference to the accompanying drawings in which example embodiments are shown. Whenever possible, the same reference numerals are used throughout the drawings to refer to the same or like parts. However, aspects may be embodied in many different forms and should not be construed as limited to the example embodiments set forth herein. These example embodiments are provided so that this disclosure will be both thorough and complete, and will fully convey the scope of the example embodiments to those skilled in the art.

For purposes of this discussion, the terms “modify”, “affix”, “deposit”, attach”, and various forms thereof are used interchangeably herein and represent the process whereby one layer is placed on another layer.

For the purposes of this discussion, the terms “hermetic seal”, “hermetically encapsulate”, “hermeticity”, and “hermetic” represent a permeability to water of less than 1×10⁻⁶ grams_{water}/meter²/day and a permeability to oxygen of less than 1×10⁻⁵ grams_{oxygen}/meter/day. The above-referenced hermeticity characteristics may be measured by any method known to one having ordinary skill in the art, including, but not limited to, a calcium patch test at 85° C. with a relative humidity of 85%, the details thereof being described at column 7, line 50 through column 10, line 55 of U.S. Pat. No. 8,115,326, which is hereby incorporated by reference in its entirety. For example, a calcium patch test can be performed by depositing a thin (e.g. 100 nanometer thick) calcium layer and/or a 200 nm thick aluminum layer on a substrate, such as by evaporation, and sealing the patch within a package in accordance with the present disclosure. One or more of such sealed packages can then be placed within an oven and subjected to environmental aging at a fixed temperature and humidity, typically 85° C. and 85% relative humidity, and for a predetermined period of time, for example 1000 hours. While the newly deposited calcium (or aluminum) appears initially as a highly reflecting metallic mirror, if water and oxygen penetrate the sealed package, the metallic calcium reacts and disintegrates. In some instances such disintegration may appear as opaque white flaky crust which can be quantified with an optical measurement. In other instances this disintegration the deposited calcium may be eroded to the point that the deposited film becomes transparent. In any event, observation of the patch, for example at a 10× magnification, can readily uncover the disintegration. In some instances visual examination by eye, without magnification, can reveal disintegration. A sealed package in accordance with the present disclosure can be deemed hermetic if a calcium patch survives 100 hours without visible signs of disintegration when exposed to the foregoing environment.

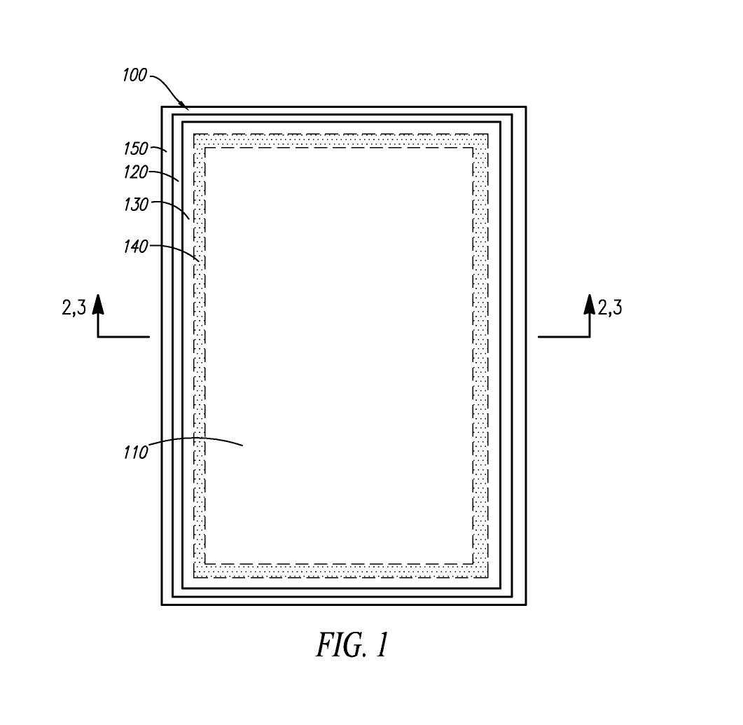

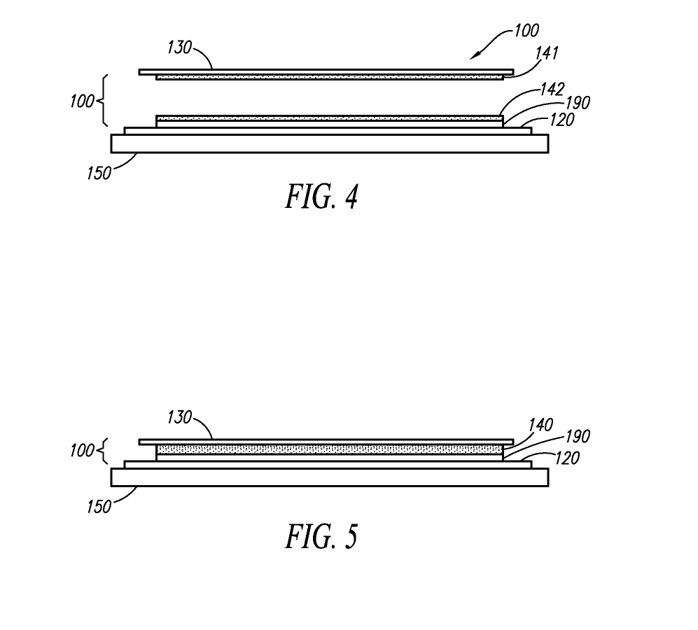

FIGS. 1-5 illustrate one example of a flexible display device package 100 in accordance with aspects of the disclosure. In some examples, the flexible display device package 100 may be supported by a carrier substrate 150 during a manufacturing process. While the carrier substrate 150 may comprise a glass carrier, the carrier substrate 150 may comprise a ceramic carrier, resin carrier or a carrier substrate fabricated from materials configured with sufficient rigidity and structural integrity to carry the flexible display device package 100 during a manufacturing process and/or when handling after manufacturing the flexible display device package 100.

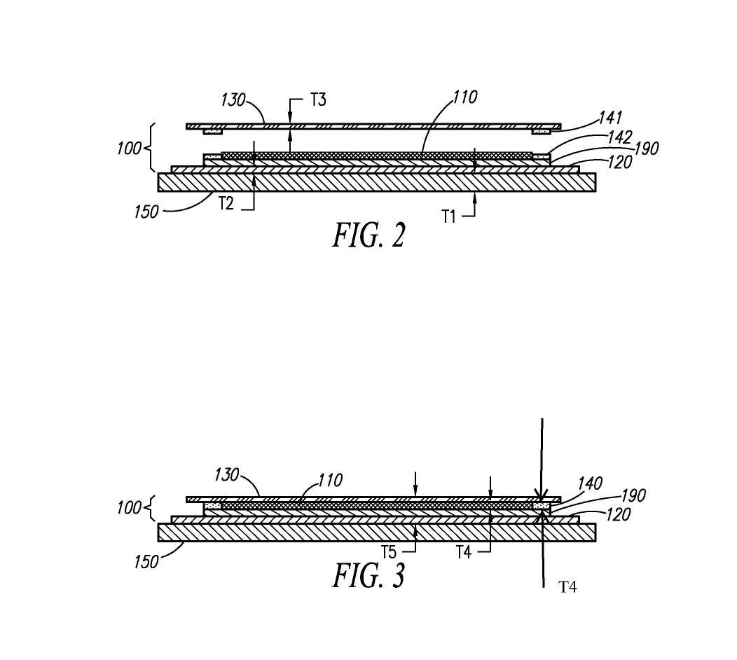

The carrier substrate 150 can provide rigidity to the flexible display device package 100 during the manufacturing process. As such, the manufactured flexible display device package 100 may be easily transported and may even be processed with glass manufacturing equipment normally designed for use with glass sheets having a greater thickness and/or greater rigidity than the flexible display device package 100. Moreover, the carrier substrate 150 may provide a support substrate for manufacturing the flexible display device package 100. As shown in FIG. 2, the carrier substrate 150 may have a thickness T1 of from about 0.3 mm to about 1 mm, such as from about 0.3 mm to about 0.7 mm.

Still further, in some examples, the carrier substrate 150 may be dimensionally larger than the flexible display device package 100. For example, with reference to FIGS. 1 and 2, the carrier substrate 150 may have a peripheral portion 151 that provides protection to the relatively delicate outer peripheral portions of the flexible display device package 100 during transport and gripping portions for a manufacturing or material handling apparatus to allow handling of the flexible display device package 100. The peripheral portion 151 may extend beyond an outer periphery of the flexible display device package 100. In some examples, as illustrated in FIG. 1, the peripheral portion 151 may laterally circumscribe the entire outer periphery of the flexible display device package 100.

As further illustrated in FIGS. 1-5, the flexible display device package 100 further includes a polymer substrate 120 that provides the flexible display device package 100 with wear and corrosion resistance while maintaining structural integrity under high temperature, such as high-temperature processing conditions. In one example, the polymer substrate 120 can include a polyimide provided alone or in combination with other materials. In still further examples, the polymer substrate 120 may consist essentially of a polyimide without additional materials that would materially affect the characteristics of the polyimide material.

As shown in FIG. 2, the polymer substrate 120 can include a thickness T2 of from about 1 micron to about 500 microns, such as from about 1 micron to about 50 microns, such as from about 2 microns to about 20 microns.

As shown in FIGS. 1-5, the flexible display device package 100 further comprises a barrier 190 deposited on the polymer substrate 120. The barrier 190 may comprise one of a metal film, a glass film, and a combination thereof. However, the composition of the barrier 190 is not limited thereto, and may be any effective composition known to one having ordinary skill in the art. In addition, the barrier 190 may be a silicon backplane layer or an equivalent thereof.

As shown in FIGS. 1-4, the flexible display device package 100 further comprises a display device 110. In some examples, the display device may include an organic light-emitting diode (OLED) although other display devices may be provided in further examples. In some examples, the display device 110 may be affixed or deposited on the barrier 190. In addition or alternatively, the display device 110 may be situated between a flexible glass sheet 130, a seal 140, and the barrier 190. However, embodiments described herein are not limited thereto. For example, the display device 110 may be affixed or deposited on a separate substrate and then transferred onto the barrier 190. In addition, the display device 110 may be selected as an off-the-shelf display device that is incorporated into the flexible display device package 100. Alternatively, the display device 110 may be manufactured as a step in the method of manufacturing the flexible display device package 100.

Since the polymer substrate 120 is permeable, the barrier 190 may act as a way by which oxygen and water can be kept from the display device 110 once the display device 110 is deposited on the barrier 190. The barrier 190 may be a hermetic seal between the display device 110 and the polymer substrate 120. In another example, the barrier 190 may only include the hermeticity necessary to prevent water and oxygen infiltration into the display device 110 for a period long enough to hermetically seal a top portion of the display device 110 with the flexible glass sheet 130 mentioned above and hermetically seal a second side of the polymer substrate 120 with a bottom film sheet 870, illustrated in FIG. 8, after debonding of the polymer substrate 120 from the carrier substrate 150.

The flexible display device package 100 further includes the flexible glass sheet 130 mentioned above. The flexible glass sheet 130 may comprise various types of glass, such as, but not limited to, alkaline earth boro-aluminosilicates, alkaline earth aluminosilicates, alkali phospho-aluminosilicates and alkali aluminosilicates. As another example, the flexible glass sheet 130 may comprise a thickness, two major surfaces and glass that comprises SiO₂, Al₂O₃, and two or more of B₂O₃, P₂O₅, MgO, CaO, SrO, BaO, ZnO, Na₂O, K₂O, and Li₂O. As yet another example, a glass of the flexible glass sheet 130 may comprise from about 62 mole % to about 75 mole % of SiO₂, from about 8 mole % to about 15 mole % of Al₂O₃, from about 0 mole % to about 12 mole % of B₂O₃, from about 8 mole % to about 17 mole % of RO and from about 0 mole % to about 3 mole % of P₂O₅, where RO comprises one or more of MgO, CaO, SrO, BaO and ZnO. As a further example, the glass of the flexible glass sheet 130 may comprise from about 54 mole % to about 72 mole % of SiO₂, from about 8 mole % to about 17 mole % of Al₂O₃, from about 0 mole % to about 8 mole % of B₂O₃, from about 0 mole % to about 8 mole % of RO, from about 0 mole % to about 7 mole % of P₂O₅ and from about 12 mole % to about 20 mole % of R₂O, where RO comprises one or more of MgO, CaO, SrO, BaO, and ZnO and R₂O comprises one or more of Na₂O, K₂O, and Li₂O. In some examples, the glass may be chemically strengthened glass although non-strengthened glass may be provided in further examples.

As shown in FIG. 2, the flexible glass sheet 130 has a relatively thin thickness T3 of less than about 0.3 mm, such as from about 10 microns to about 300 microns, such as from about 50 microns to about 200 microns. Providing the flexible glass sheet 130 with the relatively thin thickness of less than about 0.3 mm can provide flexible display device package 100 with the desired size and flexibility for various applications. The relatively thin flexible glass sheet 130 may provide the flexible display device package 100 with excellent transmission of display output from the display device 110 while also providing excellent wear resistance, corrosion resistance, and a hermetic barrier while maintaining structural integrity under high processing temperatures.

As shown in FIGS. 2 and 3, the flexible glass sheet 130 may be bonded to the barrier 190 (e.g., with a seal 140) to hermetically encapsulate the display device 110 between the flexible glass sheet 130 and the barrier 190. For example, as shown in FIG. 3, the seal 140, such as the illustrated peripheral seal, may be provided between the flexible glass sheet 130 and the barrier 190 to circumscribe the display device 110 to hermetically encapsulate the display device 110 between the flexible glass sheet 130 and the barrier 190. In some examples, at least part of the seal 140 may comprise an inorganic material. In some examples, once the seal 140 is formed, the entire seal 140 or a substantial portion of the seal 140 comprises an inorganic material. Providing a seal 140 as an inorganic seal can improve structural integrity of the seal under high temperature conditions. Referring to FIG. 3, the seal 140 may include a thickness T4 of from about 10 nm to about 50 microns, such as from about 500 nm to about 10 microns.

As such, the flexible glass sheet 130 may be bonded to barrier 190 by the seal 140, such as with the illustrated inorganic seal 140. In addition, the seal 140 may be hermetic to effect a hermetic thin glass encapsulation of the display device 110 on the polymer substrate 120 with the barrier 190. In order to create the seal 140 that hermetically encapsulates the display device 110 between the barrier 190 and the flexible glass sheet 130, in some examples, the flexible glass sheet 130 and the barrier 190 may each include respective sealing members 141 and 142 deposited on the flexible glass sheet 130 and the barrier 190. Indeed, as shown in FIG. 2, a surface of the flexible glass sheet 130 may be provided with a first sealing member 141 while the barrier 190 may be provided with a second sealing member 142. The sealing members 141 and 142 may comprise sealants that hermetically seal the flexible glass sheet 130 and the barrier 190 together with the seal 140 after contacting each other during a sealing process. One or both of the sealing members may comprise sealants with one or more of lead free solder, gold eutectics, a metal silicide, and a glass seal, although other sealants may be used in further examples.

The flexible display device package 100 can comprise a relatively thin package. The relatively thin nature of the flexible display device package 100 can be incorporated in applications where a relatively thin device profile is desired. The relatively thin nature of the flexible display device package 100 can also help minimize the overall weight of the relatively thin device without compromising the structural integrity of the flexible display device package. Referring to FIG. 3, the overall thickness T5 of the flexible display device package 100 can be within a range of from about 30 microns to about 400 microns, such as from about 50 microns to about 150 microns.

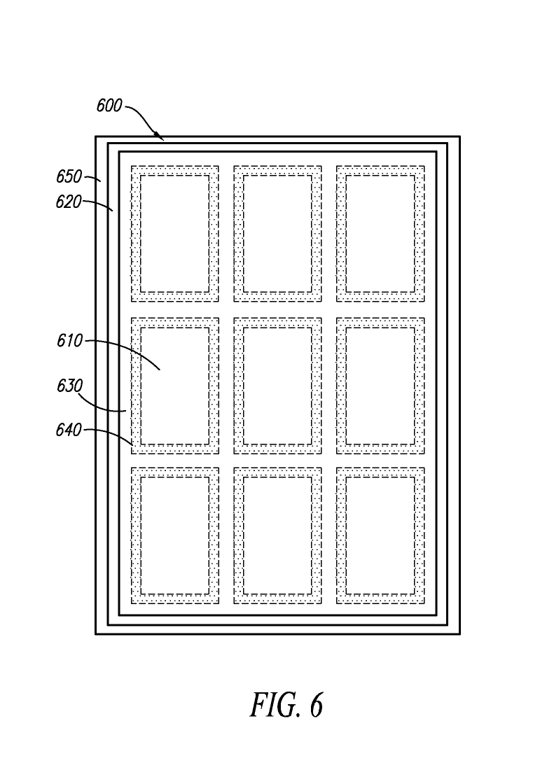

The flexible display device package 100 of FIGS. 1-5 illustrates examples where a single display device 110 is affixed or deposited on the barrier 190 deposited on the polymer substrate 120. In further examples, a plurality of display devices may be affixed or deposited on one or more barriers deposited on one or more polymer substrates. For example, FIG. 6 is a schematic top view illustrating an example where multiple flexible display device packages 600 are supported by a carrier substrate 650. The carrier substrate 650 may be similar or identical to the carrier substrate 150 discussed with respect to FIGS. 1-5 above. The multiple flexible display device packages 600 can each be formed with a corresponding display device 610 affixed or deposited on a barrier (not shown) that is deposited on a polymer substrate 620 such as a single polymer substrate. The polymer substrate 620 and the barrier may be respectively similar or identical to the polymer substrate 120 and the barrier 190 discussed with respect to FIGS. 1-5 above.

As further illustrated, the multiple flexible display device packages 600 may be formed with one or more flexible glass sheets 630 that may be similar or identical to the flexible glass sheet 130 discussed with respect to FIGS. 1-5 above. In the illustrated example, a single flexible glass sheet 630 may cover the entire area on which multiple display devices 610 are each affixed or deposited on one or more of the barriers to effect hermetic encapsulation of the display devices 610 within the flexible glass sheet 630 and the one or more barriers. In further examples, each flexible display device package 600 may include a seal 640 that may be similar or identical to the seal 140 of FIGS. 1-5 discussed above. In just one example illustrated in FIG. 6, a plurality of seals 640 may be provided that each circumscribe a corresponding one of the display devices 610 such that the plurality of display devices 610 are each hermetically sealed between the flexible glass sheet 630 and the barrier and isolated from one another.

In some examples, the multiple flexible display device packages 600 may be subsequently divided (e.g., by separating the polymer substrate 620, the barrier 690, and the flexible glass sheet 630) into individual flexible display device packages 600 that may be similar or identical to the flexible display device package 100 of FIGS. 1-5. In another example, a flexible glass sheet 630 may be pre-cut to subsequently hermetically encapsulate each of the affixed or deposited display devices 610 on the barrier prior to separating. In an example in which the barrier is provided across an entirety of the polymer substrate 620, the barrier and the polymer substrate 620 would need to be separated to separate the multiple flexible display devices 600 from one another. In an example in which multiple barriers are provided to correspond to multiple flexible display device packages 600, only the polymer substrate 620 would need to be separated to separate the multiple flexible display device packages 600 from one another. Providing multiple flexible display device packages 600 together may simplify fabrication and/or handling of the individual flexible display device packages. Unless otherwise indicated, features of the flexible display device packages 600 and its various components illustrated in FIG. 6 may be similar or identical to the flexible display device package 100 and its various components illustrated in FIGS. 1-5.

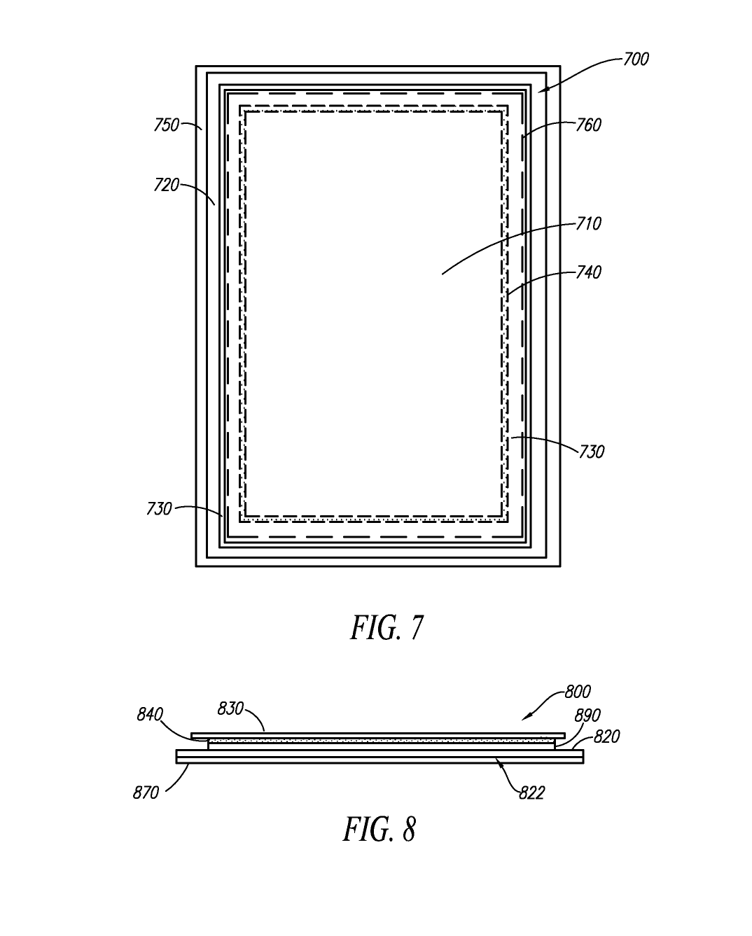

Any of the flexible display device packages 100, 600 may comprise an optional second seal circumscribing the first seal. FIG. 7 illustrates one example configuration of a flexible display device package 700. As is illustrated in the flexible display device package 700 of FIG. 7, a flexible glass sheet 730 may be bonded to a barrier (not shown) by a second seal 760 as well as a first seal 740. In one example, the second seal 760 can comprise an organic seal although an inorganic seal may be provided in further examples. In one particular embodiment, the second seal 760 comprises an organic seal while the first seal comprises an inorganic seal.

Unless otherwise indicated, the flexible display device package 700 may be similar or identical to the flexible display device package 100 described with respect to FIGS. 1-5 above or the flexible display device packages 600 described with respect to FIG. 6 above. The flexible glass sheet 730 may be similar or identical to the flexible glass sheets 130, 630 discussed above. Moreover, the first seal 740 may be similar or identical to the seal 140, 640 discussed above. In addition, the barrier may be similar or identical to the barrier 190 discussed above. Further, the polymer substrate 720 may be similar or identical to the polymer substrate 120, 620 discussed above. Herein, the discussion with respect to the flexible display device package 700 and its various components illustrated in FIG. 7 may correspond with the flexible display device package 100 and its various components illustrated in FIGS. 1-5 and/or the flexible display device packages 600 and its various components illustrated in FIG. 6.

In one example, the flexible display device package 700 can be supported by a carrier substrate 750 similar or identical to the carrier substrate 150 discussed with respect to FIGS. 1-5 above. The first seal 740 hermetically encapsulates the display device 710 between the flexible glass sheet 730 and the barrier. As such, the first seal 740 illustrated in FIG. 7 may be hermetic and in some examples may be an inorganic seal. Moreover, the first seal 740 may comprise lead free solder, gold eutectics, a metal silicide, a glass seal, or another sealing configuration.

As further illustrated in FIG. 7, the second seal 760 may be formed between the barrier and the flexible glass sheet 730 at a portion of the barrier and the flexible glass sheet 730 that is positioned outside of the first seal 740. As such, the second seal 760 circumscribes the first seal 740 while the first seal 740 circumscribes the display device 710. The second seal 760 may be an organic seal that circumscribes the first seal 740. The second seal 760 may be configured to strengthen the bond between the barrier and the flexible glass sheet 730 and may even be positioned to protect the edges of the flexible glass sheet 730. For example, the second seal 760 may optionally extend over the outer peripheral edge of the flexible glass sheet 730 to act as a bumper while also extending between the barrier and the flexible glass sheet 730 to act as a second seal between the barrier and the flexible glass sheet 730. The second seal 760 may comprise one of an ultraviolet (UV) curable sealing mater and a thermoplastic material, but is not limited thereto.

Any of the flexible display device packages 100, 600, 700 may optionally comprise a bottom film sheet configured to hermetically encapsulate a second side of the polymer substrate. For example, as shown in FIG. 8, a flexible display device package 800 is illustrated without a carrier substrate. As in FIGS. 1-5, the flexible display device package 800 may comprise a display device (not shown). The display device may be situated between a flexible glass sheet 830, a seal 840 and a barrier 890. The flexible display device package 800 may additionally comprise a bottom film sheet 870 bonded to a second side 822 of a polymer substrate 820 to hermetically encapsulate the polymer substrate 820 in order to further protect the display device after the carrier substrate has been removed. The bottom film sheet 870 may comprise one of metal foil, glass film and polymer film, but is not limited thereto. Herein, the discussion with respect to the flexible display device package 800 and its various components illustrated in FIG. 8 may correspond with the flexible display device package 100 and its various components illustrated in FIGS. 1-5, the flexible display device package 600 and its various components illustrated in FIG. 6 and the flexible display device package 700 and its various components illustrated in FIG. 7.

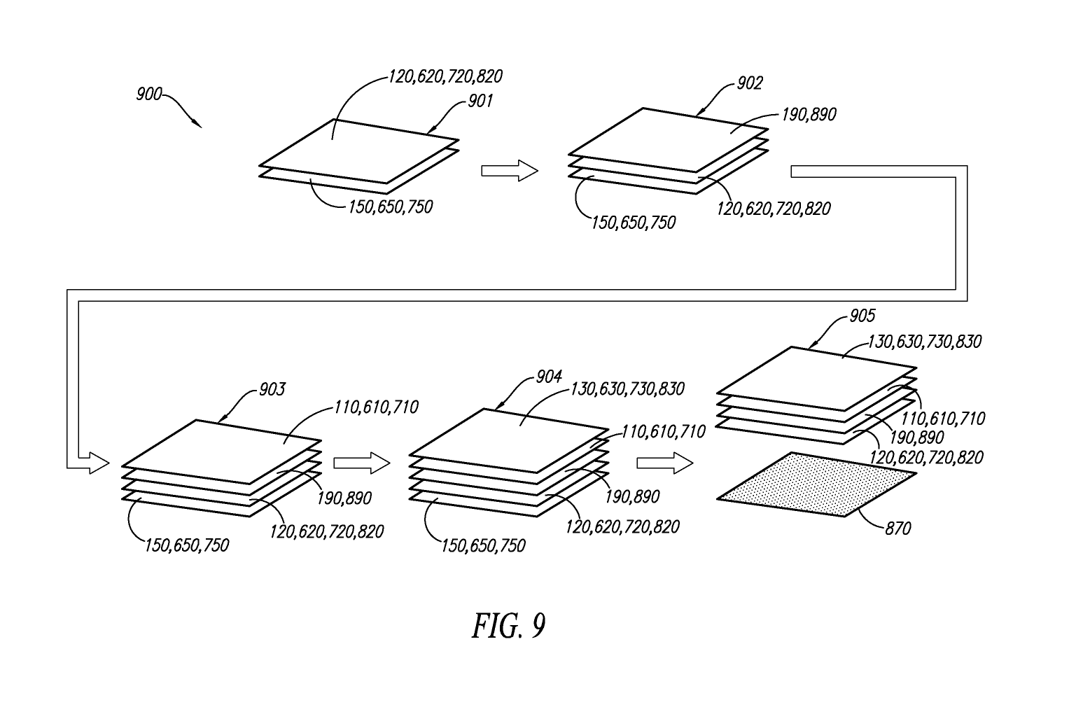

FIG. 9 is a flow diagram illustrating example methods (900) of manufacturing a flexible display device package. Herein, the discussion with respect to the method 900 may correspond with the flexible display device packages 100, 600, 700, 800 and their various components illustrated in FIGS. 1-8.

As illustrated in FIGS. 1 and 9, a polymer, may be deposited (901) onto the carrier substrate 150, 650, 750 to form the polymer substrate 120, 620, 720, 820. As previously indicated, the polymer deposited onto the carrier substrate 150, 650, 750 may comprise a polyimide provided alone or in combination with other materials. In further examples, the polymer deposited on the carrier substrate 150, 650, 750 may consist of a polyimide alone without any other material. In still further examples, the polymer deposited on the carrier substrate 150, 650, 750 may consist essentially of a polyimide without additional materials that would materially affect the characteristics of the polyimide material.

The polymer substrate 120 may be formed by various methods, including the lamination of polymer sheets to the carrier substrate 150, 650, 750 and the subsequent debonding of the carrier substrate 150, 650, 750 from the polymer substrate 120, 620, 720, 820. Another method of forming the polymer substrate 120, 620, 720, 820 may comprise spinning or coating the carrier substrate 150, 650, 750 with a polymer monomer or a pre-polymer solution, curing the spun or coated material to form a thin layer forming the polymer substrate 120, 620, 720, 820, and then debonding the carrier substrate 150, 650, 750 from the polymer substrate 120, 620, 720, 820. However, the methods by which the polymer substrate 120, 620, 720, 820 is formed are not limited to the examples mentioned above.

After the deposition of the polymer (901) onto the carrier substrate 150, 650, 750, optionally, a barrier 190, 890 may be deposited (902) onto the polymer substrate 120, 620, 720, 820. As previously noted, the barrier 190, 890 may comprise one of a metal film, a glass film, and a combination thereof. However, the composition of the barrier 190, 890 is not limited thereto, and may be any effective composition known to one having ordinary skill in the art. In addition, the barrier 190, 890 may be a silicon backplane layer or an equivalent thereof.

After the deposition of the barrier 190, 890, a display device 110, 610, 710, such as an OLED device, may be affixed or deposited on (903) the barrier 190, 890. Then, a flexible glass sheet 130, 630, 730, 830 may be bonded (904) to the barrier 190, 890 to hermetically encapsulate the display device 110, 610, 710 between the flexible glass sheet 130, 630, 730, 830 and the barrier 190, 890.

While the disclosed example method 900 comprises the display device 110, 610, 710 being affixed or deposited on the barrier 190, 890, embodiments described herein are not limited thereto. For example, the display device 110, 610, 710 may be affixed or deposited on a separate substrate and then transferred onto the barrier 190, 890. In addition, the display device 110, 610, 710 may be selected as an off-the-shelf display device that is transferred onto the flexible display device packages 100, 600, 700, 800.

In one example of the bonding (904) of the flexible glass sheet 130, 630, 730, 830 to the barrier 190, 890, the flexible glass sheet 130, 630, 730, 830 and the barrier 190, 890 may comprise sealing members 141 and 142 deposited on the flexible glass sheet 130, 630, 730, 830 and the barrier 190, 890, respectively. The sealing members 141 and 142 may comprise sealants that, after contacting each other, hermetically seal the flexible glass sheet 130, 630, 730, 830 and the barrier 190, 890 together. In this example, the sealants of the sealing members 141 and 142 may comprise, but are not limited to, one of lead free solder, gold eutectics, or other sealing materials. However, further example embodiments will be described herein in which the sealing members 141 and 142 may comprise different sealants from those described above. The sealing members 141 and 142 may serve to form the seal 140 between the flexible glass sheet 130, 630, 730, 830 and the barrier 190, 890. The seal 140 formed by the example sealants described above may be a metal-to-metal seal.

In an example of forming the seal 140 using one of lead free solder and gold eutectics, the lead free solder or gold eutectics may be initially patterned as metal lines on the barrier 190, 890 and flexible glass sheet 130, 630, 730, 830, thereby creating example embodiments of the sealing members 141 and 142. Then, the barrier 190, 890 may be aligned with the flexible glass sheet 130, 630, 730, 830 to bring the flexible glass sheet 130 and the barrier 190, 890 into close proximity to one another, thereby contacting sealing member 141 with sealing member 142. Then, the sealing members 141 and 142 may be laser welded, induction heated, contacted with a localized heat source, or sealed using other appropriate methods to form the hermetic seal 140 between the flexible glass sheet 130, 630, 730, 830 and the barrier 190, 890.

In another example of the bonding (904) of the flexible glass sheet 130, 630, 730, 830 to the barrier 190, 890, the sealant of sealing members 141 and 142 may comprise a metal silicide or any other appropriate material. In an example of forming the seal 140 with a metal silicide, at least one of aluminum, molybdenum, cobalt, nickel, and other appropriate materials may be deposited as one of the sealing member 141 of the flexible glass sheet 130, 630, 730, 830 and the sealing member 142 of the barrier 190, 890. A layer of silicon may be deposited as another one of the sealing member 141 of the flexible glass sheet 130, 630, 730, 830 and the sealing member 142 of the barrier 190, 890. In one example, the layer of silicon may comprise amorphous silicon. The sealing members 141 and 142 may then be reacted together by localized heating or other appropriate heating methods known to one having ordinary skill in the art, thereby forming the metal silicide representing the seal 140. The metal silicide may be formed at temperatures as low as about 300° C., which can easily be accomplished through laser illumination, induction heating, contact with a localized heat source, or other appropriate heating methods.

In yet another example of the bonding (904) of the flexible glass sheet 130, 630, 730, 830 to the barrier 190, 890, the flexible glass sheet 130, 630, 730, 830 may be sealed to the barrier 190, 890 with a glass seal. In an example of forming the seal 140 with a glass seal, a glass frit may be deposited on the flexible glass sheet 130, 630, 730, 830 as the sealing member 141. The glass frit may include, for example, binders, solvents and filler materials such as coefficient of thermal expansion-modifying filler materials (e.g. beta eucryptite or beta quartz). The glass frit may then be heated to burn off binders and solvents from the glass frit. A contact area, including oxide, metal, or other appropriate materials, may then be deposited on the barrier 190, 890 to form the sealing member 142. Then, the sealing member 141 and the sealing member 142 may be contacted and heated locally to form the seal 140 as a hermetic glass seal. The local heating may be accomplished through laser annealing, induction heating, contact with a localized heat source, or other appropriate heating methods.

As is illustrated in FIGS. 7 and 9, in a further example of the bonding (904) of the flexible glass sheet 730 to the barrier (not shown in FIG. 7), in addition to the first seal 740 that bonds the flexible glass sheet 730 and the barrier together to hermetically encapsulate the mounted display device 710, the flexible glass sheet 730 may be optionally be further sealed to the barrier through a second seal 760. The second seal 760 may comprise an organic seal although inorganic seals may be provided in further examples. The second seal 760 may circumscribe the hermetic sealing material and, in some examples, may be formed by organic sealing materials, such as, but not limited to, UV-curable sealing material and inert thermoplastic material. The UV-curable sealing material may be a low viscosity material, such as a UV-curable epoxy or acrylate or other appropriate materials known to one having ordinary skill in the art. The inert thermoplastic material may be polyetherimide or other appropriate materials.

In one example including UV-curable sealing material as the organic sealing material, the UV-curable sealing material may be deposited around an edge of the flexible glass sheet 730, where it can wick between the flexible glass sheet 730 and the barrier. Then, the wicked UV-curable sealing material may be cured by UV illumination or other appropriate heating methods known to one having ordinary skill in the art and optionally followed by localized heating to form the second organic seal 760.

In another example including inert thermoplastic material as the organic sealing material, a film of the inert thermoplastic material may be deposited on the flexible glass sheet 730 prior to the hermetic sealing of the flexible glass sheet 730 to the barrier. The film may organically seal the flexible glass sheet 730 to the barrier by localized heating or other appropriate heating methods known to one having ordinary skill in the art. The film may organically seal the flexible glass sheet 730 to the barrier through the bonding of the sealing member 141 and the sealing member 142 by laser illumination, localized heating, or other appropriate heating methods.

As is illustrated in FIGS. 8 and 9, after the bonding (904) of the flexible glass sheet 130, 630, 730, 830 to the barrier 190, 890, the carrier substrate 150, 650, 750 may be debonded from a second side 822 of the polymer substrate 120, 620, 720, 820. After the debonding, the bottom film sheet 870 maybe bonded (905) to the second side of the polymer substrate 120, 620, 720, 820 to hermetically encapsulate the polymer substrate 120, 620, 720, 820, further serving to protect the mounted display device 110, 610, 710 (not shown in FIG. 8) from environmental contaminants. An example embodiment of the bottom film sheet 870 may comprise metal foil, glass film, polymer film, or other appropriate materials. The bonding (905) may be accomplished by any of the above-referenced methods described with respect to the bonding (904) of the flexible glass sheet 130, 630, 730, 830 to the barrier 190, 890 or any other appropriate method.

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

What is claimed is:

1. A flexible display device package, comprising:
a barrier on a polymer substrate;
a display device on the barrier; and
a flexible glass sheet bonded to the barrier with a hermetic seal to hermetically encapsulate the display device between the flexible glass sheet and the barrier,
wherein the flexible glass sheet comprises a thickness of less than about 0.3 mm.

2. The flexible display device package of claim 1, further comprising:
a bottom film sheet bonded to a second side of the polymer substrate to hermetically encapsulate the polymer substrate.

3. The flexible display device package of claim 2, wherein the bottom film sheet comprises one of metal foil, glass film, polymer film, and any combination thereof.

4. The flexible display device package of claim 1, wherein the flexible glass sheet is bonded to the barrier by one of lead free solder, gold eutectics, a metal silicide, and a glass seal.

5. The flexible display device package of claim 4, wherein the flexible glass sheet is further bonded to the barrier by an organic seal circumscribing the hermetic seal.

6. The flexible display device package of claim 5, wherein the organic seal comprises one of a UV-curable sealing material and a thermoplastic material.

7. The flexible display device package of claim 1, wherein the polymer substrate comprises a polyimide.

8. The flexible display device package of claim 1, wherein the barrier comprises one of a metal film, a glass film, and a combination thereof.

9. A method of manufacturing a flexible display device package, the method comprising:
depositing a barrier on a polymer substrate;
depositing a display device on the barrier; and
bonding a flexible glass sheet to the barrier to hermetically encapsulate the display device between the flexible glass sheet and the barrier,
wherein the flexible glass sheet comprises a thickness of less than about 0.3 mm.

10. The method of claim 9, further comprising bonding a bottom film sheet to a second side of the polymer substrate to hermetically encapsulate the polymer substrate.

11. The method of claim 10, wherein the bottom film sheet comprises one of metal foil, glass film, polymer film, and any combination thereof.

12. The method of claim 9, wherein the bonding of the flexible glass sheet comprises sealing the barrier to the flexible glass sheet with one of lead free solder, gold eutectics, a metal silicide, and a glass seal.

13. The method of claim 12, further comprising, when the barrier is sealed to the flexible glass sheet with one of lead free solder and gold eutectics:
depositing the polymer substrate on a carrier substrate prior to the depositing of the barrier; and
aligning the barrier with the flexible glass sheet after the depositing of the barrier and prior to the bonding of the flexible glass sheet.

14. The method of claim 12, wherein, when the barrier is sealed to the flexible glass sheet by the metal silicide, the sealing comprises reacting one or more of aluminum, molybdenum, cobalt and nickel deposited on one of the flexible glass sheet and the barrier with a silicon layer deposited on another of the flexible glass sheet and the barrier.

15. The method of claim 12, wherein, when the barrier is sealed to the flexible glass sheet by the glass seal, the sealing comprises depositing a glass frit on the flexible glass sheet, depositing an oxide or metal contact area on the barrier, and contacting the glass frit and the contact area while heating to form the glass seal.

16. The method of claim 9, wherein the bonding of the flexible glass sheet comprises hermetically sealing the flexible glass sheet to the barrier with a hermetic sealing material, and organically sealing the flexible glass sheet to the barrier with an organic sealing material,
wherein the organic sealing material circumscribes the hermetic sealing material.

17. The method of claim 16, wherein the organic sealing material comprises a UV-curable sealing material,
wherein the organically sealing comprises wicking the UV-curable sealing material between the flexible glass sheet and the barrier and curing the UV-curable sealing material.

18. The method of claim 16, wherein the organically sealing comprises depositing a film of thermoplastic material on the flexible glass sheet to seal the flexible glass sheet to the barrier.

19. The method of claim 9, wherein the barrier comprises one of a metal film, a glass film, and a combination thereof.
